(19) United States
(12) Patent Application Publication
(10) Pub. No.: US 2013/0126993 A1
(43) Pub. Date: May 23, 2013

(54) ELECTROMECHANICAL TRANSDUCER AND METHOD OF PRODUCING THE SAME

(71) Applicants: Kazutoshi Torashima, Yokohama-shi (JP); Takahiro Akiyama, Kawasaki-shi (JP)

(72) Inventors: Kazutoshi Torashima, Yokohama-shi (JP); Takahiro Akiyama, Kawasaki-shi (JP)

(73) Assignee: CANON KABUSHIKI KAISHA, Tokyo (JP)

(21) Appl. No.: 13/813,396

(22) PCT Filed: Jul. 26, 2011
(86) PCT No.: PCT/JP2011/067579

§ 371 Date: Jan. 30, 2013

(30) Foreign Application Priority Data
Aug. 2, 2010 (JP) 2010-173659

(51) Int. Cl. H01L 21/18; B81B 3/00

(52) U.S. Cl. CPC H01L 21/185; B81B 3/0021
USPC 257/416; 438/459

(57) ABSTRACT

The present invention relates to an electromechanical transducer and a method of producing it, in which the substrate rigidity is maintained to prevent the substrate from being broken during formation of dividing grooves or a film.

The electromechanical transducer includes a plurality of elements each having at least one cell. An insulating layer is formed on a first substrate, and gaps are formed in the insulating layer. A second substrate is bonded to the insulating layer provided with the gaps. Then, dividing grooves are formed in the first substrate and are at least partially filled with an insulating member. Then, the thickness of the second substrate bonded to the insulating layer is reduced to form a film.

### TECHNICAL FIELD

The present invention relates to an electromechanical transducer such as a capacitive micromachined ultrasonic transducer array that is used as, for example, an ultrasonic transducer and relates to a method of producing the electromechanical transducer.

### BACKGROUND ART

Micromachine components that are produced by micromachining technologies can be applied to fabrication at micrometer scale, and various functional microdevices have been realized using these micromachine components. Capacitive micromachined ultrasonic transducers (CMUTs) using such technologies have been studied as alternatives of piezoelectric devices. In such a CMUT, ultrasonic waves can be transmitted and received using vibration of a vibration film, and, in particular, excellent broadband characteristics can be easily obtained in a liquid.

A capacitive micromachined ultrasonic transducer array having a single-crystal silicon vibration film formed on a silicon substrate by, for example, bonding has been proposed (see PTL 1). In the constitution described in PTL 1, a silicon film having a single-crystal silicon vibration film is used as a common electrode, and a silicon substrate is divided. The divided silicon substrate is used as signal extraction electrodes to constitute a capacitive micromachined ultrasonic transducer array. Furthermore, in order to enhance the rigidity of the device, a frame structure is provided in the peripheries of the signal extraction electrodes. In addition, in a method of producing this constitution, an oxide film and gaps are formed on a first silicon on insulator (SOI) substrate, and the active layer of the first SOI substrate is divided to separate each capacitive micromachined ultrasonic transducer element. Then, a second SOI substrate is bonded, and the handle layer and the buried oxide (BOX) layer are removed to form a silicon film having a single-crystal silicon vibration film. Furthermore, in order to electrically connect the active layer and the handle layer of the first SOI substrate, the silicon film having the single-crystal silicon vibration film, the oxide film, and the active layer and the BOX layer of the first SOI substrate are etched, and a film of conductor is formed. Then, in order to electrically separate the silicon film having the single-crystal silicon vibration film and the conductor, the silicon film having the single-crystal silicon vibration film is divided to produce a capacitive micromachined ultrasonic transducer array.

In a capacitive micromachined ultrasonic transducer array in which a single-crystal silicon vibration film is formed on a silicon substrate by, for example, bonding as in above, the silicon substrate can be used as signal extraction electrodes by dividing the silicon substrate. In such a case, since the silicon substrate is divided, the rigidity of the transducer array decreases, and breakage may be caused by, for example, thermal stress during mounting. Furthermore, when the silicon film having the single-crystal silicon vibration film is exposed in a process of producing the capacitive micromachined ultrasonic transducer array, the single-crystal silicon vibration film may be broken in a subsequent process such as application of heat or processing of the rear surface of the silicon substrate. In such a case, the production yield rate of the capacitive micromachined ultrasonic transducer array tends to decrease.

### CITATION LIST

### Patent Literature

PTL 1 U.S. Patent Publication No. US2008/0048211

### SUMMARY OF INVENTION

In view of the above-mentioned problems, the method of the present invention for producing an electromechanical transducer including a plurality of elements each having at least one cell includes the following steps: a step of forming an insulating layer on a first substrate and forming gaps in the insulating layer; a step of bonding a second substrate to the insulating layer provided with the gaps; a step of reducing the thickness of the second substrate; a step of forming dividing grooves in the first substrate to form a plurality of elements on the opposite side to the side of the insulating layer provided with the gaps; and a step of filling at least partially the dividing grooves of the first substrate with an insulating member. The step of forming dividing grooves in the first substrate to form a plurality of elements and the step of filling at least partially the dividing grooves of the first substrate with an insulating member are conducted after the step of bonding the second substrate to the insulating layer. Furthermore, the step of reducing the thickness of the second substrate is conducted after the step of filling at least partially the dividing grooves of the first substrate with an insulating member. Typically, the first and second substrates are first and second silicon substrates, respectively.

Furthermore, in view of the above-mentioned problems, the electromechanical transducer of the present invention includes a plurality of elements each having at least one cell. The cell includes a silicon substrate, a single-crystal silicon vibration film, and a vibration film-holding portion for holding the vibration film in such a manner that a gap is formed between one surface of the silicon substrate and the vibration film. The cell is characterized by being produced by the above-described method of producing an electromechanical transducer. Typically, the electromechanical transducer is constituted as a capacitive micromachined ultrasonic transducer array.

According to the present invention, formation of the dividing grooves in the first substrate and filling of the dividing grooves with an insulating member are performed after bonding of the second substrate. Therefore, the substrate rigidity can be maintained even if the dividing grooves are formed in the first substrate. In addition, the thickness of the second substrate is reduced after filling of the dividing grooves of the first substrate with an insulating member. By doing so, since the thickness of the second substrate can be reduced after the improvement in rigidity of the first substrate, breakage of the substrate during the thickness-reducing step can be prevented.

### BRIEF DESCRIPTION OF DRAWINGS

FIGS. 1A to 1F are cross-sectional views illustrating an embodiment and an example of the method of producing an electromechanical transducer of the present invention.

FIG. 2 is a top view illustrating the embodiment and the example of the electromechanical transducer of the present invention.

FIG. 3 is a cross-sectional view illustrating Example 2 relating to an electromechanical transducer of the present invention.

FIG. 4 is a cross-sectional view illustrating Example 3 relating to an electromechanical transducer of the present invention.

FIGS. 5A and 5B are diagrams illustrating Example 4 relating to an electromechanical transducer of the present invention.

### DESCRIPTION OF EMBODIMENTS

The present invention is characterized as follows. In a so-called junction type electromechanical transducer and a method of producing it, the step of forming dividing grooves in a first substrate for separating and insulating between the elements that are formed on the first substrate and the step of filling at least partially the dividing grooves with an insulating member are conducted after the step of bonding a second substrate, which will be reduced in thickness later. Then, the step of reducing the thickness of the second substrate is conducted after the step of filling at least partially the dividing grooves with an insulating member. Based on this point of view, the electromechanical transducer and the method of producing it of the present invention fundamentally have the constitutions described in the Summary of Invention. The electromechanical transducer to which the present invention can be applied is typically a junction type CMUT, but the present invention can be also applied to an electromechanical transducer having a magnetic film, which can be constituted as a junction type such as a magnetic micromachined ultrasonic transducer (MMUT).

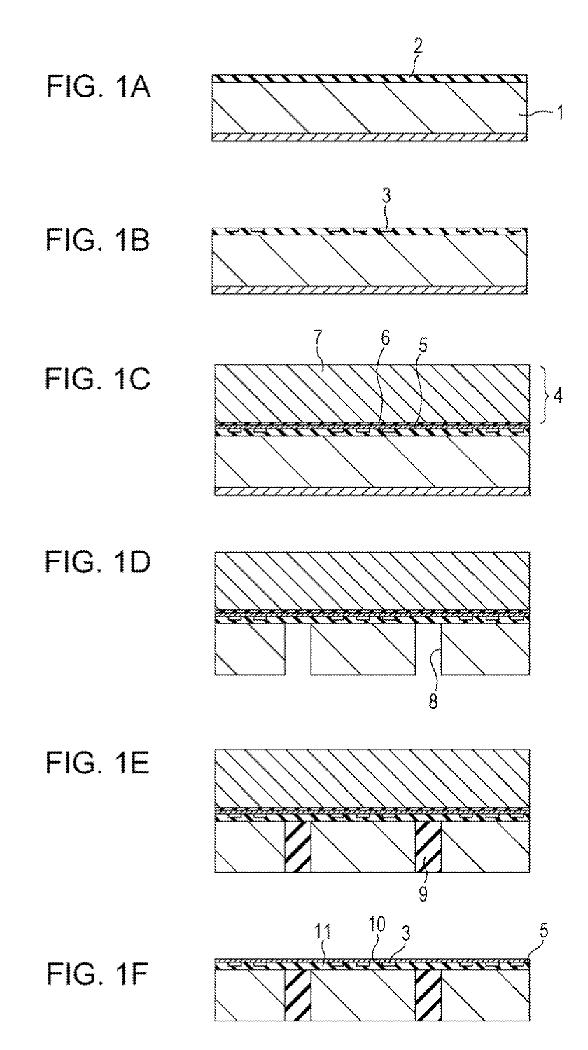

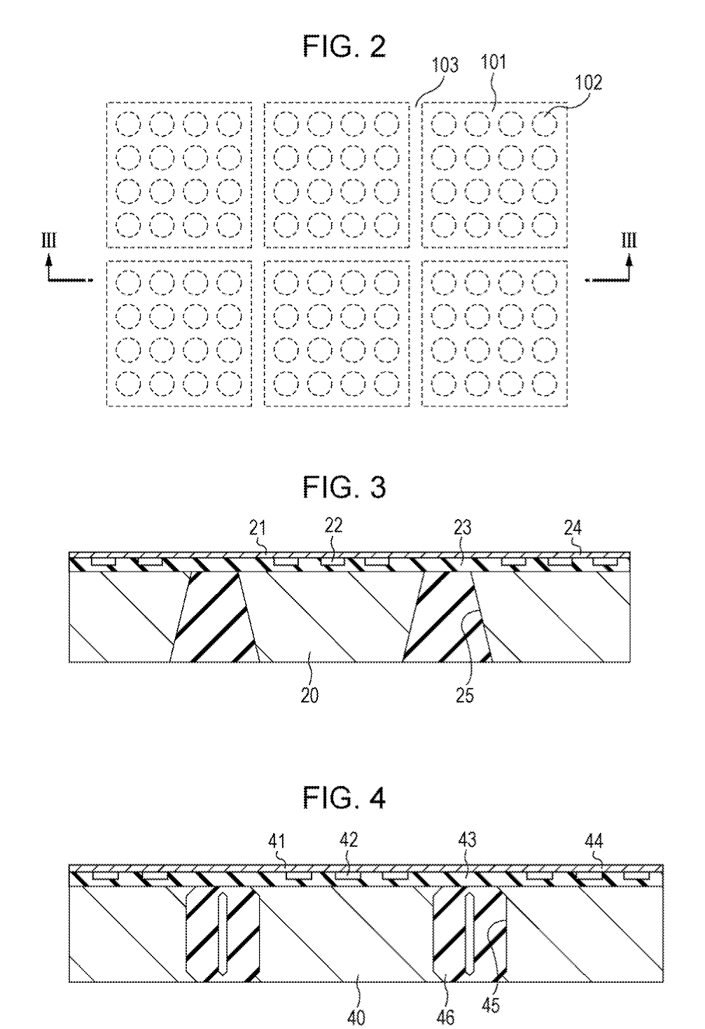

Embodiments and examples of the electromechanical transducer and the method of producing it of the present invention will be described below. The constitution and the driving principle of a capacitive micromachined ultrasonic transducer array as an embodiment of the present invention will be described with reference to FIGS. 2 and 3. FIG. 2 is a top view of the capacitive micromachined ultrasonic transducer array of the embodiment, and FIG. 3 is a cross-sectional view taken along the line III-III of FIG. 2. The capacitive micromachined ultrasonic transducer array includes a plurality of elements 101 each having at least one cell 102. In FIG. 1, only six elements 101 are drawn, but the number of the elements is not limited. Similarly, each element 101 is composed of sixteen cells 102, but the number of the cells is not limited. The shape of the cell is circular in this example, but may be, for example, quadrangular or hexagonal. The plurality of elements 101 are electrically separated from one another by the dividing grooves 103.

As shown in FIG. 3, the cell 102 is constituted of a single-crystal silicon vibration film 21, gaps 22, a vibration film-holding portion 23 for holding the vibration film 21, and a silicon substrate 20. The holding portion 23 holds the vibration film 21 in such a manner that the gaps 22 are formed between one surface of the silicon substrate 20 and the vibration film 21. The vibration film 21 hardly has a residual stress, compared with a vibration film (e.g., silicon nitride film) formed by lamination, and has low variation in thickness and low variation in spring constant. Therefore, the variation in performance of elements and the variation in performance of cells are small. The holding portion 23 can be an insulator and may be formed of, for example, silicon oxide or silicon nitride. When the holding portion 23 is not an insulator, in order to insulate between the silicon substrate 20 and the vibration film 21, for example, an insulating layer is necessarily formed on the silicon substrate 20. The silicon film 24 having the vibration film 21 is used as a common electrode for the elements and, therefore, can be a low-resistant substrate that easily forms an ohmic contact and has a resistivity of 0.1 Ωcm or less. The term “ohmic contact” refers to that the resistance value is constant regardless of the current direction and the voltage level. In order to improve the conduction characteristics of the vibration film 21, a thin aluminum film may be formed on the silicon film 24 having the vibration film 21. The silicon substrate 20 can be used as signal extraction electrodes by forming dividing grooves 25 therein. Thus, since the silicon substrate 20 is used as the signal extraction electrodes, it can be a low-resistant substrate having a resistivity of 0.1 Ωcm or less. On the rear surface of the silicon substrate 20, a metal film (not shown) is formed for easily forming an ohmic contact of the silicon substrate 20 serving as the signal extraction electrode for each element. For example, a lamination structure of titanium/platinum/gold is formed. The dividing grooves 25 are filled with an insulating member. With this constitution, the substrate rigidity of a capacitive micromachined ultrasonic transducer array can be increased.

The driving principle of the embodiment will now be described. When the capacitive micromachined ultrasonic transducer array receives ultrasonic waves, a DC voltage is applied to the silicon film 24 having the single-crystal silicon vibration film 21 with a voltage application means (not shown). Since the vibration film 21 deforms by receiving ultrasonic waves, the distance between the vibration film 21 and the silicon substrate 20 changes to cause a change in capacitance. This change in capacitance causes an electric current in each portion of the silicon substrate 20 divided by the dividing grooves 25. This electric current is converted into a voltage with a current-voltage converter (not shown), and, thereby, the ultrasonic waves can be received as a voltage. In addition, the vibration film 21 can be vibrated by an electrostatic force through application of a DC voltage and an AC voltage to the silicon film 24 having the single-crystal silicon vibration film 21. With this, ultrasonic waves can be transmitted.

The method of producing the capacitive micromachined ultrasonic transducer array of the embodiment will be described with reference to FIG. 1. First, as shown in FIG. 1A, an insulating film 2 is formed on a first silicon substrate 1. The first silicon substrate 1 can be a low-resistant substrate having a resistivity of 0.1 Ωcm or less. The insulating film 2 is made of, for example, silicon oxide or silicon nitride and can be formed by, for example, chemical vapor deposition (CVD) or thermal oxidation. Then, as shown in FIG. 1B, gaps 3 are formed. The gaps 3 can be formed by, for example, dry etching or wet etching. The gaps 3 constitute the capacitors of the capacitive micromachined ultrasonic transducer array. Then, as shown in FIG. 1C, a second silicon substrate 4 is bonded on the insulating film 2. The second silicon substrate 4 can be bonded, for example, with a resin or by direct or fusion bonding. The direct bonding is a method in which the bonding interfaces are activated for bonding. The fusion bonding is a method in which a polished silicon substrate or a silicon substrate provided with a SiO₂ film thereon is disposed on the insulating film 2 and they are heated to bond them with an intermolecular force. By bringing surfaces into contact with each other in the air, an OH-group derived from Si—OH form a hydrogen bond with another OH-group. By heating to several hundred degrees centigrade in this state, an H₂O molecule is eliminated from the OH-groups, Si atoms binds to each other via an oxygen atom. Furthermore, by heating to 1000° C. or higher, the oxygen diffuses into a silicon wafer, and a bond between the Si atoms is formed, resulting in an increase in adhesion force. Furthermore, the second silicon substrate 4 may be an SOI substrate, which is a substrate having a structure in which a silicon oxide layer (BOX layer) 6 is disposed between a silicon substrate (handle layer) 7 and a surface silicon layer (active layer) 5. Since the active layer 5 of the SOI substrate has low variation in thickness, the variation in thickness of the single-crystal silicon vibration film can be reduced, and the variation in spring constant of the single-crystal silicon vibration film can be reduced. Consequently, the variation in performance of elements of the capacitive micromachined ultrasonic transducer array can be reduced.

Then, as shown in FIG. 1D, dividing grooves 8 are formed in the first silicon substrate 1 on the opposite side to the side of the insulating layer 2 provided with the gaps 3. The dividing grooves 8 can be formed by etching. By forming the dividing grooves 8, the first silicon substrate 1 is electrically divided and can be thereby used as a plurality of electrodes. Each portion of the divided silicon substrate can be used as the signal extraction electrode of each element of the capacitive micromachined ultrasonic transducer array. Then, as shown in FIG. 1E, the dividing grooves 8 are filled with an insulating member 9. The insulating member 9, filling with which the dividing grooves 8, is not limited as long as it is an insulator and may be, for example, silicon oxide or a resin. In a case of silicon oxide formed by thermal oxidation or from tetraethoxysilane (TEOS), since the process uniformity is high, the film can be easily formed on the side walls of the dividing grooves 8. In addition, in the case of silicon oxide formed from a TEOS film, since a thick film can be easily formed, the widths of the dividing grooves 8 may be large. By doing so, the distance between the elements can be large to decrease the capacitance between the elements. Consequently, crosstalk between the elements can be reduced. The dividing grooves 8 may not be completely filled with the insulating member 9 as long as the rigidity of the substrate can be ensured.

Then, as shown in FIG. 1F, the thickness of the second silicon substrate 4 is reduced to form a silicon film 5 having the single-crystal silicon vibration film 10. In order to make the thickness of the silicon film forming the single-crystal silicon vibration film several micrometers or less, the reduction in thickness of the second silicon substrate 4 is performed by, for example, etching, grinding, or chemical mechanical polishing (CMP). As shown in FIG. 1F, the reduction in thickness of the SOI substrate is performed by removing the handle layer 7 and the BOX layer 6. The handle layer 7 can be removed by grinding, CMP, or etching. The BOX layer 6 can be removed by etching of an oxide film (dry etching or wet etching with hydrogen fluoride, etc.). In the wet etching with, for example, hydrogen fluoride, since silicon can be prevented from being etched, the variation in thickness of the single-crystal silicon vibration film 10 due to the etching can be advantageously reduced. When the second substrate for forming the single-crystal silicon vibration film is not an SOI substrate, the thickness can be reduced to about 2 μm by, for example, back grinding or CMP. As in above, a capacitive micromachined ultrasonic transducer array including a plurality of elements having cells can be produced. The cells each include the single-crystal silicon vibration film 10, the gap 3, the vibration film-holding portion 11 for holding the vibration film 10, and the silicon substrate 1. The silicon film 5 having the vibration film 10 is used as the common electrode for the elements.

In the method of producing the capacitive micromachined ultrasonic transducer array of the embodiment, the step of forming the dividing grooves in the first substrate for electrical separation and the step of filling the dividing grooves with an insulating member are performed after bonding of the second substrate. The substrate rigidity is significantly decreased by dividing the first substrate. Therefore, in order to avoid breakage of the first substrate, a mechanism for holding the first substrate is necessary. However, in the method of the embodiment, the substrate rigidity can be maintained even if the first substrate is divided. In addition, the step of reducing the thickness of the second substrate (which will be rather like a film, depending on the degree of reduction in thickness) is conducted after the step of filling at least partially the dividing grooves of the first substrate with an insulating member. By doing so, since the thickness of the second substrate can be reduced after an increase in rigidity of the first substrate, the substrate can be prevented from being broken during the step of reducing the thickness.

If the step of processing the rear surface of the first substrate or the step of application of heat is conducted after the step of reducing the thickness of the second substrate, the vibration film may be broken to cause a decrease in production yield rate. However, in the method of the embodiment, the step of processing the rear surface of the first substrate or the step of application of heat is not conducted after the step of forming a vibration film by reducing the thickness of the second substrate. Consequently, the production yield rate can be increased. In addition, a capacitive micromachined ultrasonic transducer having a vibration film can be formed using two substrates or one substrate and one SOI substrate. Thus, the number of expensive SOI substrates can be reduced compared to a constitution using two SOI substrates, resulting in a reduction in the cost.

The capacitive micromachined ultrasonic transducer array produced by the method of the embodiment can improve the device strength. Therefore, the capacitive micromachined ultrasonic transducer array of the embodiment can be prevented from being broken even if stress is applied to the array when it is connected to a PCB substrate, IC, etc. In addition, when the insulating member 9 with which the dividing grooves are filled is silicon oxide formed from a TEOS film, since a thick film can be easily formed, even if dividing grooves have large widths, the grooves can be filled with the member. Since the divided silicon substrate is used as the signal extraction electrode for each element, small widths of the dividing grooves may cause parasitic capacitance and crosstalk. Accordingly, in silicon oxide formed from a TEOS film, the dividing grooves having a large width of 10 μm or more can be easily filled with the insulating film, and the above-mentioned problems can be reduced.

Furthermore, as shown in FIG. 3, the dividing grooves formed in the substrate may have a tapered shape. The term “tapered shape” means that the width of the dividing groove 25 at the surface side, on which the gaps 22 are formed, of the first substrate is smaller than that of the dividing groove 25 at the other surface side of the first substrate. Since the divided substrate is used as signal extraction electrodes, wider widths of the dividing grooves are better for decreasing parasitic capacitance between the signal extraction electrodes to reduce crosstalk. However, since the element having a large number of cells is disposed on each signal extraction electrode, the wider width of the dividing groove results in a larger distance between the elements. Therefore, an employment of the tapered shape as in this example can decrease the parasitic capacitance between the signal extraction electrodes without widening the distance between the elements. With this, a capacitive micromachined ultrasonic transducer array in which the transducers are arrayed at a high density but low in crosstalk can be formed (see Example 2 described below).

Alternatively, the dividing groove having a structure in which the width at the inner of the first substrate is wider than the widths at the both surface sides of the first substrate may be filled with an insulating member. With this constitution, the parasitic capacitance between the signal extraction electrodes can be decreased to reduce crosstalk, and also the rigidity of the capacitive micromachined ultrasonic transducer array can be improved (see Example 3 described below).

Furthermore, an insulating member in a grid-like pattern can be disposed in the dividing grooves. In this constitution, the first substrate is divided in a grid-like pattern when the dividing grooves are formed. Then, silicon oxide is formed by thermal oxidation. In formation of silicon oxide by thermal oxidation, since silicon is also oxidized, an insulating member in a grid-like pattern can be formed in the dividing grooves by dividing the silicon substrate in a grid-like pattern and then performing thermal oxidation. With this constitution, the rigidity of the capacitive micromachined ultrasonic transducer array can be improved even if the dividing grooves are not completely filled with the insulating member (see Example 4 described below).

The present invention will be described in detail with reference to more specific examples below.

### Example 1

The method of producing a capacitive micromachined ultrasonic transducer array of Example 1 will be described with reference to FIGS. 1A to 1F and 2. FIGS. 1A to 1F are cross-sectional views illustrating the method of this example, and FIG. 2 is a top view of the capacitive micromachined ultrasonic transducer array of this example. In the method of the example, first, as shown in FIG. 1A, an insulating film 2 is formed on a first silicon substrate 1. The resistivity of the first silicon substrate 1 is 0.01 Ωcm. The insulating film 2 is of silicon oxide formed by thermal oxidation and has a thickness of 400 nm. The surface roughness of the silicon oxide formed by thermal oxidation is very low, and even if the silicon oxide is formed on the first silicon substrate, the roughness of the silicon oxide is not increased by the surface roughness of the first silicon substrate, and the surface roughness, Rms, is 0.2 nm or less. In bonding by direct bonding or fusion bonding, if the surface roughness is large (e.g., an Rms of 0.5 nm or more), the bonding is difficult, and failure in bonding may occur. In the silicon oxide formed by thermal oxidation, since the surface roughness is not increased, failure in bonding hardly occurs, and the production yield rate can be increased.

Then, as shown in FIG. 1B, gaps 3 are formed. The gaps 3 can be formed by, for example, dry etching or wet etching. The depths of the gaps are 200 nm. The gaps 3 constitute the capacitors of the capacitive micromachined ultrasonic transducer array. Then, as shown in FIG. 1C, a second silicon substrate 4 is bonded by fusion bonding. As the second silicon substrate, an SOI substrate is used, and the SOI substrate is bonded with the active layer 5 thereof. The active layer 5 will be used as a silicon film having a single-crystal silicon vibration film. The active layer 5 has a thickness of 1 μm, a thickness variation of ±5% or less, and a resistivity of 0.01 Ωcm.

Then, as shown in FIG. 1D, dividing grooves 8 are formed in the first silicon substrate 1 by silicon deep etching. The dividing grooves 8 are constituted so as to pass through the first silicon substrate 1 and have a width of 10 μm. With the dividing grooves 8, the first silicon substrate 1 is electrically divided and can be thereby used as a plurality of electrodes. Each portion of the divided silicon substrate can be used as the signal extraction electrode of each element of the capacitive micromachined ultrasonic transducer array. Then, as shown in FIG. 1E, the dividing grooves 8 are filled with an insulating member 9. The insulating member 9 with which the dividing grooves are filled is silicon oxide formed from a TEOS film. In the case of silicon oxide formed from a TEOS film, since the process uniformity is high, the film can be easily formed on the side walls of the dividing grooves 8.

Then, as shown in FIG. 1F, the thickness of the second silicon substrate 4 is reduced to form a silicon film 5 having the single-crystal silicon vibration film 10. As shown in FIG. 1F, the reduction in thickness of the SOI substrate used as the second silicon substrate is performed by removing the handle layer 7 and the BOX layer 6. The handle layer 7 can be removed by, for example, grinding, CMP, or etching. The BOX layer 6 is removed by wet etching with hydrogen fluoride. Since the wet etching with hydrogen fluoride can prevent silicon from being etched, the variation in thickness of the single-crystal silicon vibration film 10 due to the etching can be low.

In the method of producing the capacitive micromachined ultrasonic transducer array of this example, the step of forming the dividing grooves 8 in the first silicon substrate 1 for electrical separation and the step of filling the dividing grooves 8 with the silicon oxide 9 formed from a TEOS film are conducted after bonding of the second silicon substrate 4. The effect of this procedure is as described above. Furthermore, the step of reducing the thickness of the second silicon substrate 4 is conducted after the step of filling the dividing grooves 8 of the first silicon substrate 1 with the silicon oxide 9 formed from a TEOS film. The effect of this procedure is also as described above. In also this method, the step of processing the rear surface of the first silicon substrate or the step of application of heat is not conducted after the step of reducing the thickness of the second silicon substrate 4 to form the silicon film 5 having the single-crystal silicon vibration film 10. Therefore, the production yield rate can be further increased.

### Example 2

The capacitive micromachined ultrasonic transducer array and the method of producing it of Example 2 will be described with reference to FIG. 3. The capacitive micromachined ultrasonic transducer array of Example 2 can be produced by almost the same method as in Example 1. FIG. 3 is a cross-sectional view of the capacitive micromachined ultrasonic transducer array of this example, and the top view thereof is almost the same as that shown in FIG. 2.

The cells 102 and the elements 101 of the capacitive micromachined ultrasonic transducer array of this example have the structures shown in FIG. 3. The vibration film-holding portion 23 is of silicon oxide formed by thermal oxidation. Since the silicon film 24 having the single-crystal silicon vibration film 21 is used as the common electrode for the elements, it is made so as to easily form an ohmic contact. The resistivity of the silicon film 24 is 0.01 Ωcm. The silicon substrate 20 is used as signal extraction electrodes and has a resistivity of 0.01 Ωcm. The insulating member 25 with which the dividing grooves 25 are filled is an epoxy resin. With this constitution, the substrate rigidity of the capacitive micromachined ultrasonic transducer array can be increased. The driving principle of this example is as described above.

In this example, as shown in FIG. 3, the dividing grooves 25 formed in the first silicon substrate 20 have a tapered shape. In the tapered shape, the width of the dividing groove 25 at the surface side, on which the gaps 22 are formed, of the first silicon substrate 20 is smaller than that of the dividing groove 25 at the other surface side of the first silicon substrate 20. As in this example, by forming the dividing grooves 25 in the tapered shape, the parasitic capacitance between the signal extraction electrodes can be decreased without widening the distance between the elements. With this, a capacitive micromachined ultrasonic transducer array in which the transducers are arrayed at a high density but low in noise can be formed.

### Example 3

The capacitive micromachined ultrasonic transducer array and the method of producing it of Example 3 will be described with reference to FIG. 4. The capacitive micromachined ultrasonic transducer array of Example 3 can be produced by almost the same method as in Example 1. The constitution of the capacitive micromachined ultrasonic transducer array of Example 3 is approximately the same as that of the capacitive micromachined ultrasonic transducer array of Example 2. As shown in FIG. 4, the cell includes a single-crystal silicon vibration film 41, a gap 42, a vibration film-holding portion 43 for holding the vibration film 41, and a silicon substrate 40. The silicon film 44 having the vibration film 41 is used as the common electrode for the elements.

In the capacitive micromachined ultrasonic transducer array of this example, the dividing groove 45 has a structure in which the width at the inner of the first silicon substrate 40 is wider than the widths at the both surface sides of the first silicon substrate 40, and the dividing groove 45 is filled with an insulating member 46. In this constitution, a silicon substrate with its principal plane having a crystal orientation of (100) is used as the first silicon substrate 40, and vertical dividing grooves are formed by silicon deep etching. Subsequently, anisotropic wet etching with tetramethylammonium hydroxide (TMAH) is performed to form the dividing grooves. The insulating member 46 is silicon oxide formed from a TEOS film.

By this constitution, a part of the distance between the signal extraction electrodes can be widened without widening the distance between the elements. Consequently, the parasitic capacitance between the signal extraction electrodes can be decreased. With this, a capacitive micromachined ultrasonic transducer array in which the transducers are arrayed at a high density but low in noise can be formed. Furthermore, the dividing grooves 45 are partially filled with the insulating member 46, which can decrease the parasitic capacitance, since the capacitance between signal extraction electrodes is lower in air or in vacuum. By the above-described constitution, the parasitic capacitance can be decreased, and the rigidity of the capacitive micromachined ultrasonic transducer array can be increased.

### Example 4

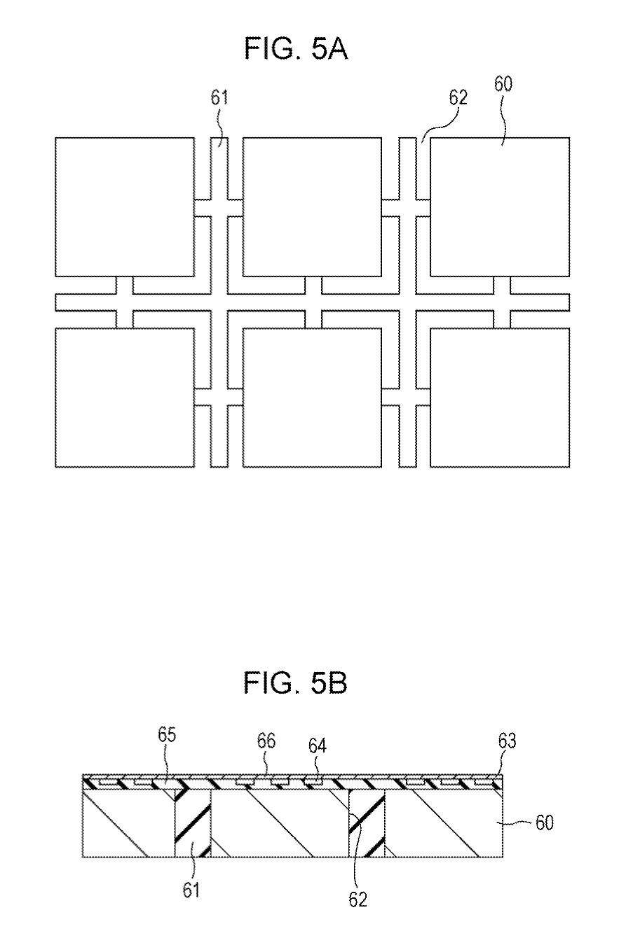

The capacitive micromachined ultrasonic transducer array and the method of producing it of Example 4 will be described with reference to FIGS. 5A and 5B. The capacitive micromachined ultrasonic transducer array of Example 4 can be produced by almost the same method as in Example 1. The constitution of the capacitive micromachined ultrasonic transducer array of Example 4 is approximately the same as that of the capacitive micromachined ultrasonic transducer array of Example 2. As shown in FIG. 5B, the cell includes a single-crystal silicon vibration film 66, a gap 64, a vibration film-holding portion 65 for holding the vibration film 66, and a silicon substrate 60. The silicon film 63 having the vibration film 66 is used as the common electrode of the elements.

In the capacitive micromachined ultrasonic transducer array of this example, the insulating member 61 formed in a grid-like pattern is disposed in the dividing grooves 62. In this constitution, the first silicon substrate 60 is divided in a grid-like pattern when the dividing grooves 62 are formed, and silicon oxide is formed by thermal oxidation. In formation of silicon oxide by thermal oxidation, since silicon is also oxidized, the silicon substrate is divided in a grid-like pattern. Thus, an insulating member in a grid-like pattern can be formed in the dividing grooves by oxidizing silicon through thermal oxidation. Furthermore, the dividing grooves may be filled with an insulating member. By this constitution, the rigidity of the capacitive micromachined ultrasonic transducer array can be improved even if the dividing grooves are not completely filled with the insulating member.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-173659, filed Aug. 2, 2010, which is hereby incorporated by reference herein in its entirety.

1. A method of producing an electromechanical transducer including a plurality of elements each having at least one cell, the method comprising:
forming an insulating layer on a first substrate and forming gaps in the insulating layer;
bonding a second substrate to the insulating layer provided with the gaps;
reducing the thickness of the second substrate;
forming dividing grooves in the first substrate to form a plurality of elements on the opposite side to the side of the insulating layer provided with the gaps; and
filling at least partially the dividing grooves of the first substrate with an insulating member, wherein
the step of forming dividing grooves in the first substrate to form a plurality of elements and the step of filling at least partially the dividing grooves of the first substrate with an insulating member are conducted after the step of bonding the second substrate to the insulating layer; and
the step of reducing the thickness of the second substrate is conducted after the step of filling at least partially the dividing grooves of the first substrate with an insulating member.

2. The method according to claim 1, wherein the first substrate and the second substrate are a first silicon substrate and a second silicon substrate, respectively.

3. The method according to claim 1, wherein the insulating member is silicon oxide formed from tetraethoxysilane.

4. The method according to claim 1, wherein the widths of the dividing grooves at the surface side, on which the gaps are formed, of the first substrate are smaller than those of the dividing grooves at the other surface side of the first substrate.

5. The method according to claim 1, wherein the widths of the dividing grooves at the inner of the first substrate are wider than the widths at the both surface sides of the first substrate.

6. The method according to claim 1, wherein the dividing grooves are formed in a grid-like pattern, and the insulating member is formed in a grid-like pattern so as to be disposed in the dividing grooves.

7. An electromechanical transducer comprising:
a plurality of elements each having at least one cell including a silicon substrate, a single-crystal silicon vibration film, and a vibration film-holding portion for holding the vibration film in such a manner that a gap is formed between one surface of the silicon substrate and the vibration film,
wherein the electromechanical transducer is produced by a method of producing an electromechanical transducer according to claim 1.

8. The electromechanical transducer according to claim 7, being constituted as a capacitive micromachined ultrasonic transducer array.
